(19) United States
(12) Patent Application Publication
(10) Pub. No.: US 2024/0243553 A1
(43) Pub. Date: Jul. 18, 2024

(54) NITRIDE SEMICONDUCTOR LASER ELEMENT

(71) Applicant: Ushio Denki Kabushiki Kaisha, Tokyo (JP)

(72) Inventor: Koichi NANIWAE, Tokyo (JP)

(73) Assignee: Ushio Denki Kabushiki Kaisha, Tokyo (JP)

(21) Appl. No.: 18/416,618

(22) Filed: Jan. 18, 2024

(30) Foreign Application Priority Data
Jan. 18, 2023 (JP) 2023-006031

(51) Int. Cl. H01S 5/22; H01S 5/183

(52) U.S. Cl. CPC H01S 5/221; H01S 5/18308

(57) ABSTRACT

In a nitride semiconductor laser element, a first epilayer including an active layer, a current confinement layer having an opening portion, and a second epilayer are formed on a semiconductor substrate. The first epilayer has an impurity concentration maximum portion where a concentration distribution of an impurity in a depth direction shows a local maximum near an interface with the current confinement layer.

### BACKGROUND

### 1. Technical Field

The present disclosure relates to a nitride semiconductor laser element.

### 2. Description of the Related Art

Semiconductor lasers (laser diodes) have a current confinement structure to locally increase a carrier density of an active layer. As the current confinement structure, an inner-stripe structure is known (JP 2003-78215 A, JP 2006-121107 A, WO 2007/066644 A). In the inner-stripe semiconductor laser, a current confinement layer including an AlN layer or the like is buried by crystal growth. The inner-stripe structure has the following advantages over a general ridge structure that is fabricated by performing dry etching on a part of a cladding layer.
There is less damage and less variation in shape and dimension, which are caused by dry etching required for the ridge structure.
A transverse optical confinement structure, which is important for a transverse mode characteristic, can be precisely fabricated by crystal growth.
A p-type contact area and a current path of a p-cladding layer can be easily expanded, which is advantageous to reduce an element resistance.

For those reasons, the inner-stripe structure has attracted attention as a technique for fabricating a high-efficiency semiconductor laser excellent in beam quality.

As a result of examination of conventional semiconductor lasers having an inner-stripe structure, the present inventors have come to recognize the following problems.

A wafer for a semiconductor laser having an inner-stripe structure is manufactured by the following manufacturing process.
1. Form a first epitaxial layer including an active layer on a semiconductor substrate by crystal growth.
2. Form a current confinement layer having a stripe-shaped opening portion on a surface of the first epitaxial layer.
3. Regrow a second epitaxial layer on the current confinement layer.

Hereinafter the epitaxial layer also referred to as epi layer.

In a case where a wafer for a GaN-based semiconductor laser is fabricated by using a conventional method, a growth rate of a part above the opening portion is relatively higher than that of a part on the current confinement layer (non-opening portion) at the time of the regrowth of the second epilayer due to a selective growth effect. As a result, flatness of the second epilayer deteriorates, which causes variation in element characteristics and reduction in reliability.

### SUMMARY

The present disclosure has been made in such circumstances, and an exemplary object of an aspect thereof is to provide a semiconductor laser having improved flatness of a second epilayer.

An aspect of the present disclosure relates to a nitride semiconductor laser element. The nitride semiconductor laser element includes a first epilayer including an active layer, a current confinement layer having an opening portion, and a second epilayer, which are formed on a semiconductor substrate. The current confinement layer has an impurity concentration maximum portion where a concentration distribution of an impurity in a depth direction shows a local maximum near an interface with the first epilayer.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional view of an element structure of a semiconductor laser element according to an embodiment;

FIG. 2 is a cross-sectional view of a semiconductor laser element according to a comparative technology;

FIG. 3 is a cross-sectional view of a semiconductor laser element according to an embodiment;

FIG. 4 shows a method of manufacturing a semiconductor laser element according to an embodiment;

FIG. 5 is a cross-sectional scanning electron microscope (SEM) image and bird's-eye-view SEM image of a semiconductor laser element according to an embodiment;

FIG. 6 is a cross-sectional scanning electron microscope (SEM) image and bird's-eye-view SEM image of a semiconductor laser element according to a comparative technology;

FIG. 7 shows a relationship between a ratio of a difference in level to a thickness of an AlN layer, an operating voltage, and an element life;

FIG. 8 shows a concentration distribution of Mg in a depth direction of a semiconductor laser element;

FIG. 9 shows a concentration distribution of B in a depth direction of a semiconductor laser element;

FIG. 10 shows an enlarged view of a portion near an impurity concentration maximum portion;

FIG. 11 shows a relationship between an area ratio r, flatness, and a current confinement effect; and

FIG. 12 is a cross-sectional view of a vertical cavity surface emitting laser (VCSEL) according to an embodiment.

### DETAILED DESCRIPTION

### Overview of Embodiments

An overview of some exemplary embodiments of the present disclosure will be described. The overview is intended as an introduction of the following detailed description or for a basic understanding of the embodiments. The overview is a simplified description of some concepts of one or more embodiments and does not limit the scope of the present invention or disclosure. Further, the overview is not a comprehensive overview of all possible embodiments or does not limit indispensable components of the embodiments. For convenience, “an embodiment” may be used to refer to one embodiment (example or modification example) or a plurality of embodiments (examples or modification examples) disclosed in the present specification.

A nitride semiconductor laser element according to an embodiment includes a first epilayer including an active layer, a current confinement layer having an opening portion, and a second epilayer, which are formed on a semiconductor substrate. The current confinement layer has an impurity concentration maximum portion where a concentration distribution of an impurity in a depth direction shows a local maximum near an interface with the first epilayer.

In this structure, an impurity piled up on a surface of the first epilayer before the current confinement layer is formed are incorporated into the current confinement layer to be formed thereafter, and the current confinement layer has the impurity concentration maximum portion at the interface with the first epilayer. Thereafter, when the current confinement layer and the second epilayer are formed, a selective growth effect between the opening portion and a non-opening portion is weakened, which improves flatness of the second epilayer.

In an embodiment, the current confinement layer may contain AlₓGa_{y}In_{1-x-y}N. Here, x and y satisfy 0≤x+y≤1, 0<x≤1, and 0≤y<1.

In an embodiment, the impurity concentration maximum portion may be a maximum value of the concentration distribution between the current confinement layer and the active layer. That is, the impurity concentration maximum portion may have a local maximum and the maximum value of the concentration distribution.

In an embodiment, the local maximum of the impurity concentration maximum portion may be higher than an average value of concentrations of the impurities contained in the current confinement layer by one or more digits.

In an embodiment, the impurity having the local maximum may be Mg or B.

In the impurity concentration maximum portion, the concentration distribution may have a full width at half maximum of 10 nm or less.

In an embodiment, the impurity having the local maximum may be Mg and have an area density of 2×10¹² cm⁻² or more and 1×10¹⁵ cm⁻² or less.

In an embodiment, the impurity having the local maximum may be B and have an area density of 2×10¹² cm⁻² or more and 1×10¹⁵ cm⁻² or less.

In an embodiment, a ratio of an arrangement area of the current confinement layer to an area of an element upper surface may be 5% or more and less than 40%.

In an embodiment, a difference in level on an element surface between the opening portion and a non-opening portion may be four times or less a thickness of the current confinement layer.

In an embodiment, the difference in level on the element surface between the opening portion and the non-opening portion may be 300 nm or less.

### EMBODIMENTS

Hereinafter, the present disclosure will be described with reference to the drawings on the basis of preferred embodiments. The same or equivalent components, members, and processes in the drawings are denoted by the same reference signs, and redundant description will be omitted as appropriate. Further, embodiments are not intended to limit the disclosure, but are merely examples, and all features described in the embodiments and combinations thereof are not necessarily essential to the disclosure.

Dimensions (e.g. thickness, length, and width) of each member in the drawings may be enlarged or reduced as appropriate for easy understanding. Further, dimensions of a plurality of members do not necessarily indicate a magnitude relationship therebetween, and, even if a certain member A is drawn thicker than another member B in the drawings, the member A may be thinner than the member B.

### EMBODIMENTS

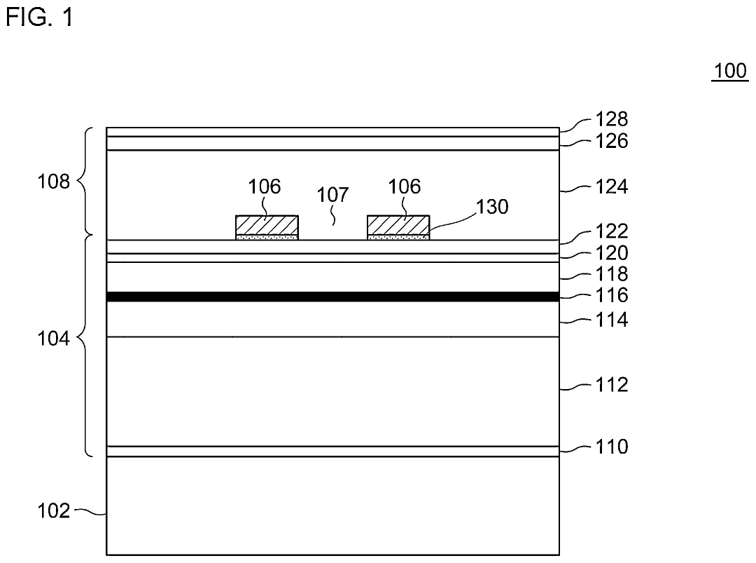

FIG. 1 is a cross-sectional view of an element structure of a semiconductor laser element 100 according to an embodiment.

The semiconductor laser element 100 has an inner-stripe current confinement structure. The semiconductor laser element 100 includes a compound semiconductor substrate 102, a first epilayer 104, a current confinement layer 106, and a second epilayer 108. The first epilayer 104, the current confinement layer 106, and the second epilayer 108 are formed in order on the compound semiconductor substrate 102.

The compound semiconductor substrate 102 is, for example, an n-type GaN substrate.

The first epilayer 104 includes a buffer layer 110, a n-type cladding layer 112, an n-side guide layer 114, an active layer 116, a p-side first guide layer 118, an electron blocking layer 120, and a p-side second guide layer 122.

The buffer layer 110 is, for example, an n-type GaN layer. The n-type cladding layer 112 is, for example, an n-type AlGaN layer or an AlGaInN layer. The n-side guide layer 114 is, for example, an n-type GaN layer.

The active layer 116 has, for example, a quantum well structure made from AlInGaN and may be a single quantum well or a multi-quantum well including a plurality of wells. The active layer may also be a single AlGaInN layer having no quantum well structure.

The p-side first guide layer 118 and the p-side second guide layer 122 are, for example, p-type GaN layers, and the electron blocking layer 120 is sandwiched therebetween.

The current confinement layer 106 is formed on the first epilayer 104. The current confinement layer 106 has a stripe-shaped opening portion 107 extending in a paper depth direction. The current confinement layer 106 can be made from AlₓGa_{y}In_{1-x-y}N (where x and y are real numbers satisfying 0≤x+y≤1, 0<x≤1, and 0<y<1). For example, the current confinement layer 106 can be made from AlN (x=1, y=0).

The second epilayer 108 includes a p-type cladding layer 124 and p-type contact layers 126 and 128. The p-type cladding layer 124 is, for example, a strained-layer superlattice (SLS) made from p-type GaN and p-type AlGaN, and the contact layers 126 and 128 are a p-type GaN layer and a high concentration p-type GaN layer, respectively.

The current confinement layer 106 has an impurity concentration maximum portion 130 where a concentration distribution of an impurity in a depth direction shows a local maximum near an interface with the first epilayer 104. In the present embodiment, the impurity concentration maximum portion 130 contains at least one of Mg and B (boron).

The above is the configuration of the semiconductor laser element 100. Advantages of the semiconductor laser element 100 become clear by contrasting with a comparative technology. Therefore, the comparative technology will be first described.

### Comparative Technology

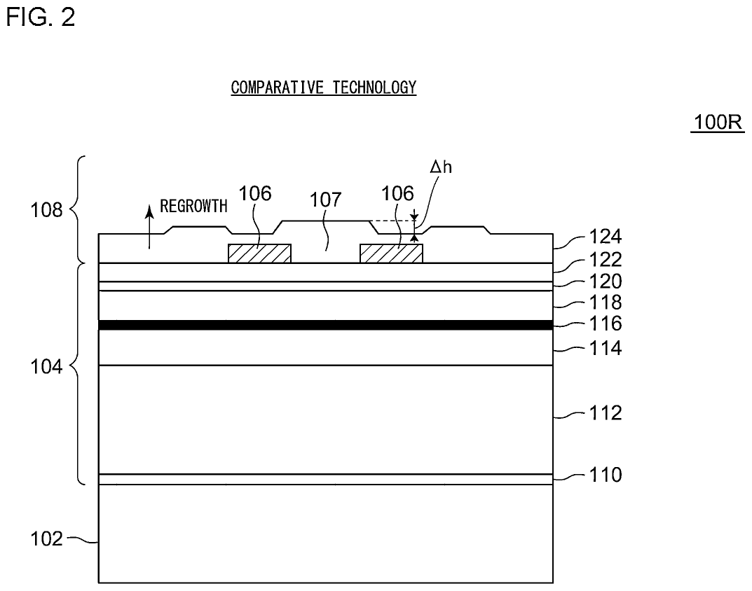

FIG. 2 is a cross-sectional view of a semiconductor laser element 100R according to a comparative technology. A cross-sectional structure of the semiconductor laser element 100R is basically similar to that of the semiconductor laser element 100 of the embodiment, but is different from the embodiment in that the impurity concentration maximum portion 130 is not formed in the first epilayer 104.

In the semiconductor laser element 100R according to the comparative technology, the first epilayer 104 and the current confinement layer 106 are formed in this order. Then, the second epilayer 108 including the p-type cladding layer 124 is formed on the current confinement layer 106 by regrowth.

In the comparative technology, a growth rate of a part above the opening portion 107 is relatively higher than a growth rate of a part on the current confinement layer 106 (non-opening portion) at the time of the regrowth of the second epilayer 108 due to a selective growth effect. As a result, flatness of the second epilayer 108 deteriorates due to a difference in level Ah near the opening portion 107, which causes variation in element characteristics and reduction in reliability.

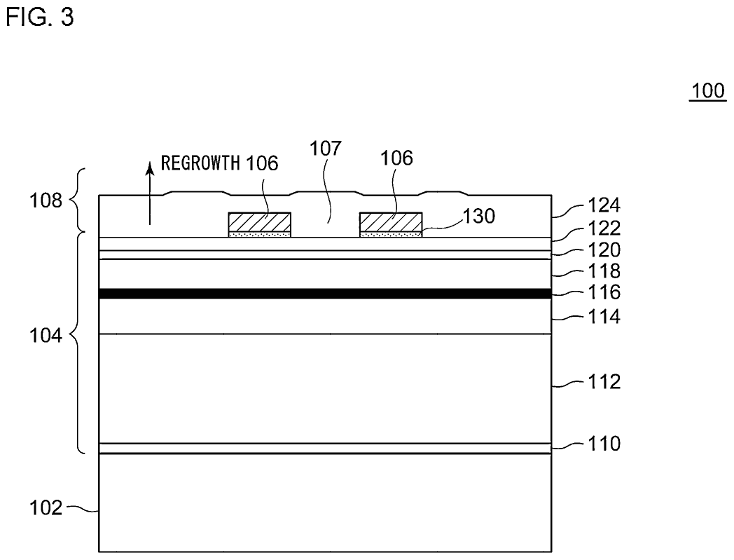

FIG. 3 shows a cross-sectional view of the semiconductor laser element 100 according to the embodiment. In the embodiment, the current confinement layer 106 has the impurity concentration maximum portion 130 at the interface with the first epilayer 104. The impurity concentration maximum portion 130 suppresses the selective growth effect at the time of the regrowth of the second epilayer 108, thereby flattening the p-type cladding layer 124. This in turn makes it possible to reduce variation in element characteristics and improve the reliability.

Subsequently, a method of manufacturing the semiconductor laser element 100 will be described.

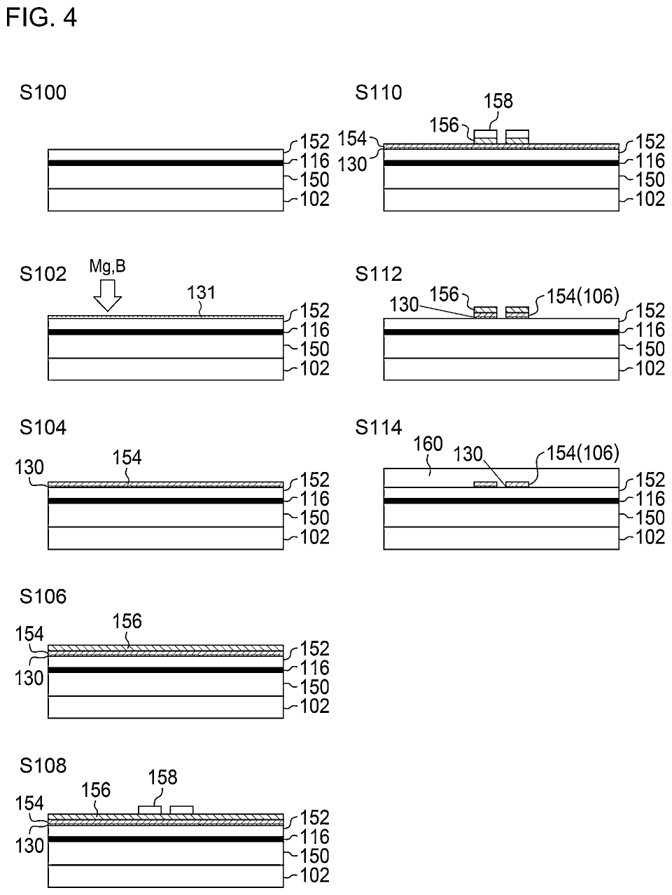

FIG. 4 shows the method of manufacturing the semiconductor laser element 100 according to the embodiment. First, a laminate of the compound semiconductor substrate 102, an n-type semiconductor layer 150, the active layer 116, and a p-type semiconductor layer 152 is formed by a process similar to conventional one (S100). The n-type semiconductor layer 150 corresponds to the buffer layer 110, the n-type cladding layer 112, and the n-side guide layer 114 of FIG. 1. The p-type semiconductor layer 152 corresponds to the p-side first guide layer 118, the electron blocking layer 120, and the p-side second guide layer 122 of FIG. 1.

Then, Mg and B, which are impurities, are deposited on a surface layer of the p-type semiconductor layer 152 (S102). The impurities may be impurities remaining in a furnace. After completion of step S100, the laminate is left in the furnace for an appropriate time, and thus impurities 131 are piled up on the surface layer of the p-type semiconductor layer 152.

Then, the process proceeds to a process of forming the current confinement layer 106. First, an AlN layer 154 to be the current confinement layer 106 later is formed (S104). In forming the AlN layer 154, the impurities deposited on the surface of the p-type semiconductor layer 152 are incorporated into the AlN layer 154 to form the impurity concentration maximum portion 130. Then, an oxide film 156 is formed (S106). Thereafter, resists 158 are patterned to have a stripe-shaped opening (S108).

Then, a part of the oxide film 156 not covered by the resists 158 is removed by dry etching (S110). Then, an opening portion is formed in the AlN layer 154 by wet etching. Thus, the current confinement layer 106 of FIG. 1 is formed (S112).

Then, the oxide film 156 is removed, thereafter the second epilayer 160 is regrown (S114).

The above is the method of manufacturing the semiconductor laser element 100. Next, a sample of the semiconductor laser element 100 according to the embodiment is prepared, and an evaluation result thereof will be described.

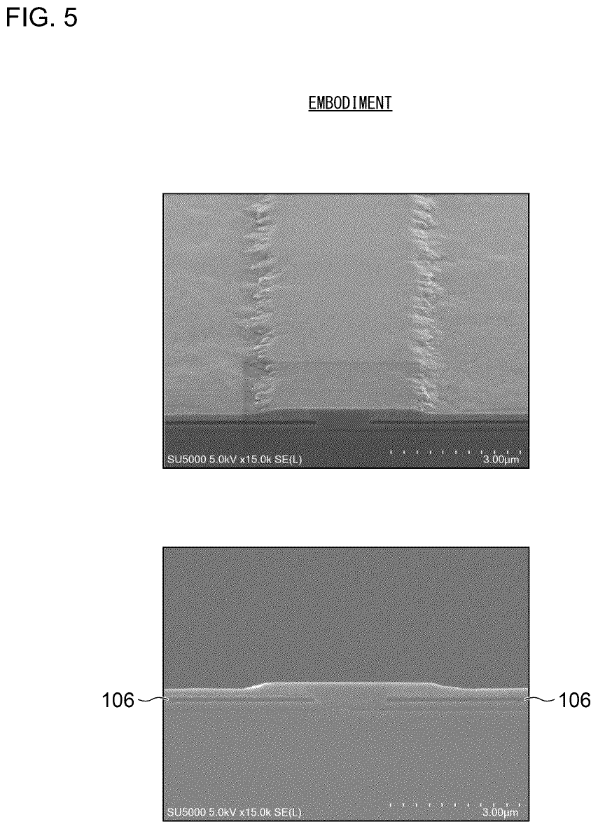

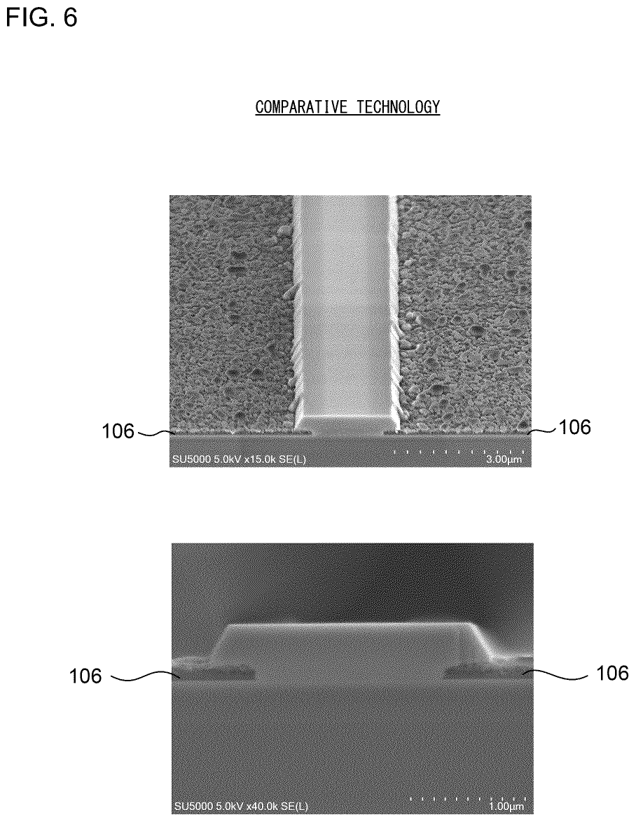

FIG. 5 is a cross-sectional scanning electron microscope (SEM) image and bird's-eye-view SEM image of the semiconductor laser element 100 according to the embodiment. FIG. 6 is a cross-sectional scanning electron microscope (SEM) image and bird's-eye-view SEM image of the semiconductor laser element 100R according to the comparative technology. In the comparative technology of FIG. 6, a height near the opening portion 107 is 0.3 μm higher than its surrounding portion. Meanwhile, in the embodiment of FIG. 5, it can be seen that the flatness is significantly improved, and the difference in level is only about 0.1 μm.

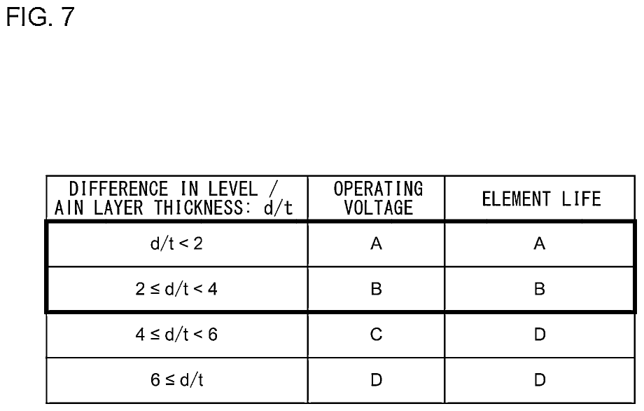

FIG. 7 shows a relationship between a ratio of the difference in level to a thickness of the AlN layer, an operating voltage, and an element life. The operating voltage and the element life were evaluated on a four-level scale from A to D. Regarding the operating voltage, A to D are index values indicating that A is the lowest and D is the highest. Regarding an operating voltage Vop, the index values can be given as follows in a case of, for example, the operating voltage Vop of an element having a length of 800 μm and an opening width of 1.5 μm.

$$A : Vop \leq 5. V$$

$$B : 5. V < Vop \leq 5.5 V$$

$$C : 5.5 V < Vop \leq 6. V$$

$$D : 6. V < Vop$$

Regarding a life t, A to D are index values indicating that A is the longest and D is the shortest. The life can be evaluated by, for example, an automatic power control operation test (APC operation test). Assuming an element having similar dimensions to those of the example of the operating voltage Vop, the life t can be defined as a time until an operating current increases by 30% as compared with a start of the test. In that case, a criterion for determining the life t can be defined as follows.

$$A : τ \geq 15 , 000 h$$

$$B : 15 , 000 h > τ \geq 10 , 000 h$$

$$C : 10 , 000 h > τ \geq 5 , 000 h$$

$$D : 5 , 000 h > τ$$

In summary, the difference in level on an element surface between the opening portion 107 and the current confinement layer 106 (non-opening portion) is desirably four times or less a thickness of the current confinement layer 106, and the difference in level on the element surface between the opening portion 107 and the current confinement layer 106 is desirably 300 nm or less. In other words, the concentration distribution of the impurity concentration maximum portion 130 may be adjusted to satisfy those conditions.

Subsequently, a result of analyzing an impurity concentration in the depth direction of the fabricated sample will be described.

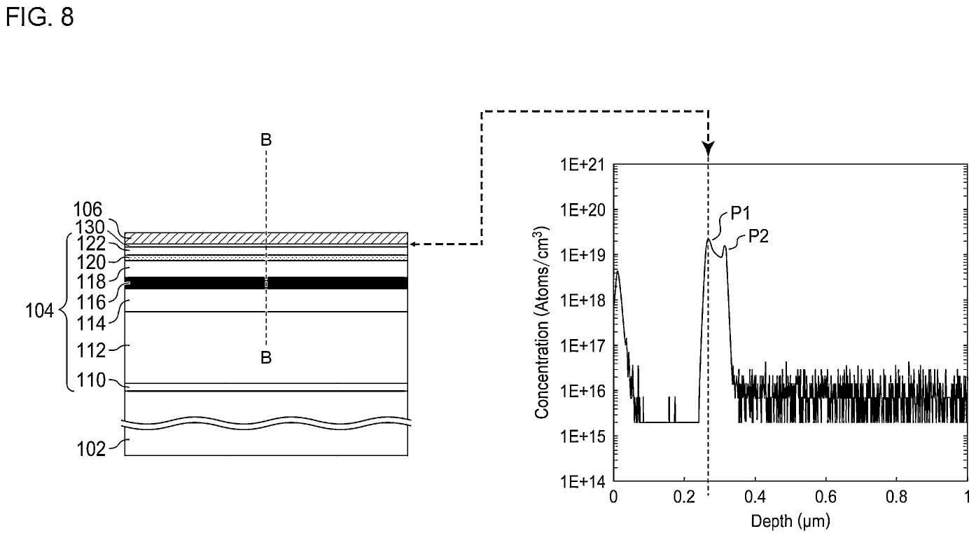

FIG. 8 shows a concentration distribution of Mg in the depth direction of the semiconductor laser element 100. The concentration distribution was measured along the line B-B in a left cross-sectional view of FIG. 8. The measured sample is a structure at the stage of forming the first epilayer 104 and the current confinement layer 106. It can be seen that the concentration distribution of Mg has a local maximum point p1 just below the current confinement layer 106. A local maximum point p2 is located just below the electron blocking layer 120 and near the uppermost layer of the p-side first guide layer 118.

In FIG. 8, the impurity concentration is high near a surface layer of the current confinement layer 106, but this is due to an influence of surface contamination of the analyzed sample and does not cause a problem when the second epilayer 108 is actually formed.

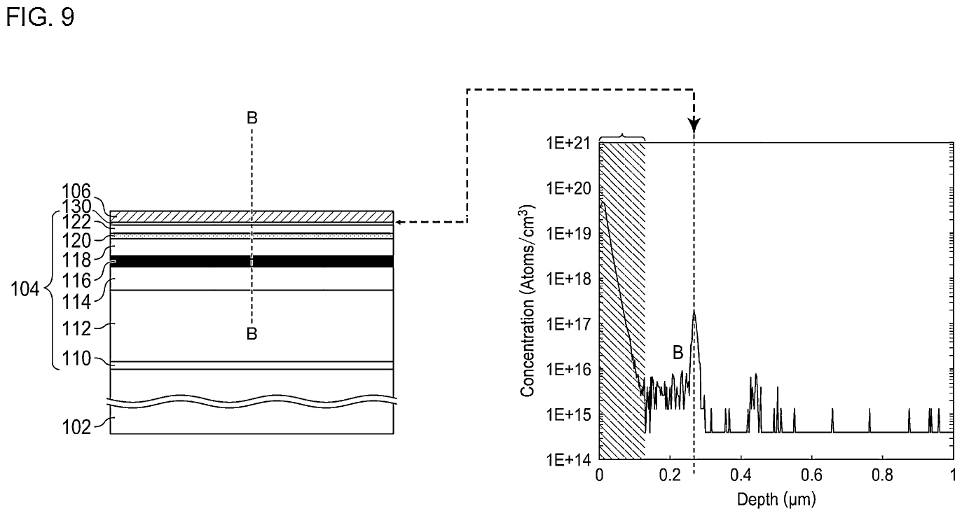

FIG. 9 shows a concentration distribution of B in the depth direction of the semiconductor laser element 100. The concentration distribution was measured along the line B-B in a left cross-sectional view of FIG. 9. The measured sample is a structure at the stage of forming the first epilayer 104 and the current confinement layer 106. It can be seen that the concentration distribution of B has a local maximum point p1 just below the current confinement layer 106. A local maximum point p2 is located just below the electron blocking layer 120 and near the uppermost layer of the p-side first guide layer 118. In FIG. 9, the impurity concentration is high near the surface layer of the current confinement layer 106, but this is due to an influence of surface contamination of the analyzed sample and does not cause a problem when the second epilayer 108 is actually formed.

As can be seen from FIGS. 8 and 9, the local maximum p1 of the impurity concentration is higher than an average value of concentrations of the impurities contained in the current confinement layer 106 by one or more digits.

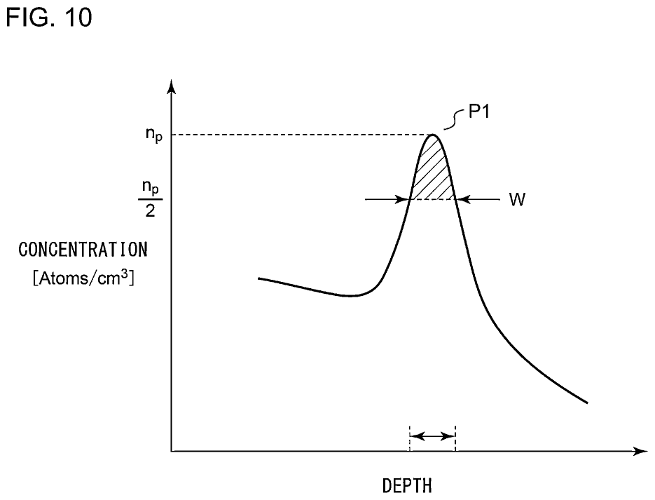

FIG. 10 shows an enlarged view of a portion near the impurity concentration maximum portion. When a peak concentration (local maximum) is np, a width that is ½ of the peak concentration is defined as a full width at half maximum W. When several samples were fabricated and evaluated under different conditions, a remarkable flattening effect was obtained when the full width at half maximum W<10 nm is satisfied, and the flattening effect was reduced when W>10 nm is satisfied. Therefore, W<10 nm is preferable.

A value, which is obtained by dividing an integral value of a hatched portion in FIG. 10 by a thickness of a single molecular layer (GaN: 0.259 nm), is defined as an area density d. At this time, a remarkable flattening effect was obtained when the following condition was satisfied with respect to an area density d_{MG} of Mg.

$$2 \times 1 {0}^{12} {cm}^{- 2} < {d}_{MG} < 1 \times 1 {0}^{15} {cm}^{- 2}$$

Also regarding an area density de of B, a remarkable flattening effect was similarly obtained when the following condition was satisfied.

$$2 \times 1 {0}^{12} {cm}^{- 2} < {d}_{B} < 1 \times 1 {0}^{15} {cm}^{- 2}$$

Thus, the area density d of the impurity is preferably within the following range.

$$2 \times 1 {0}^{12} {cm}^{- 2} < d < 1 \times 1 {0}^{15} {cm}^{- 2}$$

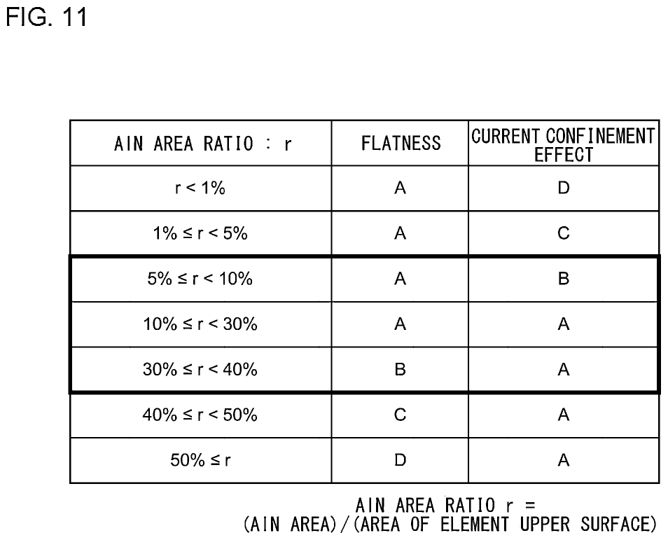

Then, the flatness and the current confinement effect were evaluated by changing an area of the current confinement layer 106. An occupancy ratio of the current confinement layer 106 to the entire surface of the semiconductor laser element 100, i.e., a ratio of the area of the current confinement layer 106 to an area of the semiconductor laser element 100, is defined as r. FIG. 11 shows a relationship between the area ratio r, the flatness, and the current confinement effect. The flatness and the current confinement effect were evaluated on a four-level scale from A to D. In A to D, A is the best, and D is the worst.

The flatness can be evaluated as follows by using a ratio r (Ah/t) of the difference in level (Ah) between the opening portion and the current confinement layer to the thickness (t) of the current confinement layer as an index.

$$A : r ( Δ h / t ) \leq 2.$$

$$B : 2. < r ( Δ h / t ) \leq 4.$$

$$C : 4. < r ( Δ h / t ) \leq 6.$$

$$D : 6. < r ( Δ h / t )$$

The current confinement effect can be evaluated as follows by using a ratio r (L/T) of a leakage current (L) to a portion other than the opening portion to a total injected current (T) as an index.

$$A : r ( L / T ) \leq 10 \%$$

$$B : 10 \% < r ( L / T ) \leq 25 \%$$

$$C : 25 \% < r ( L / T ) \leq 50 \%$$

$$D : 50 \% < r ( L / T )$$

From those results, the flattening effect and a necessary current confinement effect are obtained within the range of 5%≤r<40%. More preferably, both the flatness and the current confinement effect can be achieved to a high degree within the range of 10%≤r<30%.

### Modification Examples

It is understood by those skilled in the art that the embodiments described above are merely examples, and various modification examples are possible in combinations of the components and processing processes thereof. Hereinafter, such modification examples will be described.

### First Modification Example

In the embodiment, a structure containing both B and Mg as impurities has been described, but the present disclosure is not limited thereto. That is, the impurity concentration maximum portion 130 may contain only B or may contain only Mg. Alternatively, impurities other than B or Mg may be formed near a surface layer of the first epilayer 104 at a high concentration.

### Second Modification Example

In the embodiment, an edge emitting laser has been described, but application of the present disclosure is not limited thereto. For example, the present disclosure is also applicable to a vertical cavity surface emitting laser (VCSEL).

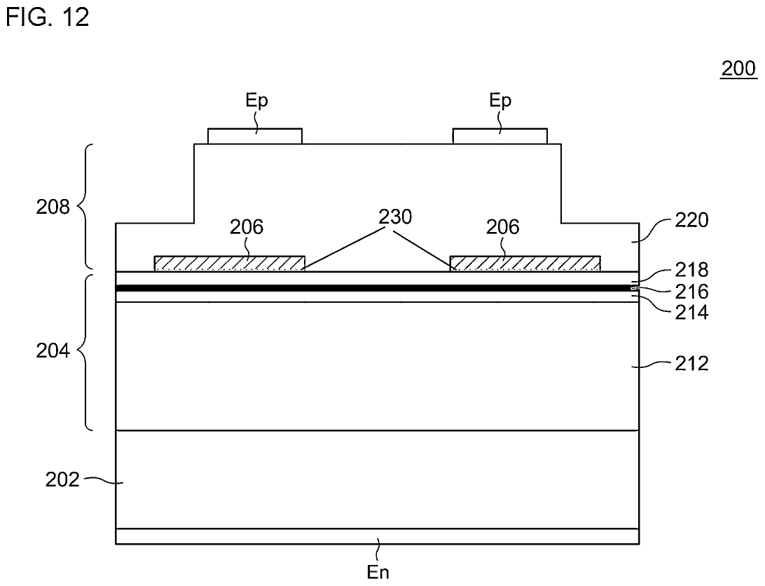

FIG. 12 shows a cross-sectional view of a VCSEL 200 according to an embodiment. The VCSEL 200 includes a semiconductor substrate 202, an n-electrode En, a p-electrode Ep, a first epilayer 204, a current confinement layer 206, and a second epilayer 208. The first epilayer 204 includes an n-type distributed Bragg reflector (DBR) layer 212, an n-side guide layer 214, an active layer 216, and a p-side guide layer 218. The second epilayer 208 includes a p-type DBR layer 220. The current confinement layer 206 has an impurity concentration maximum portion 230 at an interface with the first epilayer 204. The current confinement layer 206 has a rectangular or circular opening portion.

In the VCSEL, the p-type DBR layer 220 is formed on the current confinement layer 206. In a case where the impurity concentration maximum portion 230 is not formed, a large difference in level is generated in the p-type DBR layer 220 around the opening portion of the current confinement layer 206, but, when the impurity concentration maximum portion 230 is formed, the p-type DBR layer 220 can be flattened.

The embodiments merely illustrate the principle and application of the present disclosure, and it is understood that many modifications and changes in arrangement are made in the embodiments without departing from the spirit of the present disclosure defined in the claims.

What is claimed is:

1. A nitride semiconductor laser element comprising
a first epitaxial layer including an active layer, a current confinement layer having an opening portion, and a second epitaxial layer formed on a semiconductor substrate, wherein
the current confinement layer has an impurity concentration maximum portion where a concentration distribution of an impurity in a depth direction shows a local maximum near an interface with the first epitaxial layer.

2. The nitride semiconductor laser element according to claim 1, wherein the current confinement layer contains AlₓGa_{y}In_{1-x-y}N.

3. The nitride semiconductor laser element according to claim 1, wherein the impurity concentration maximum portion is a maximum value of the concentration distribution between the current confinement layer and the active layer.

4. The nitride semiconductor laser element according to claim 1, wherein the local maximum of the impurity concentration maximum portion is higher than an average value of concentrations of the impurities contained in the current confinement layer by one or more digits.

5. The nitride semiconductor laser element according to claim 1, wherein the impurity having the local maximum is Mg or B.

6. The nitride semiconductor laser element according to claim 1, wherein the impurity concentration maximum portion, the concentration distribution has a full width at half maximum of 10 nm or less.

7. The nitride semiconductor laser element according to claim 1, wherein the impurity having the local maximum is Mg and has an area density of 2×10¹² cm⁻² or more and 1×10¹⁵ cm⁻² or less.

8. The nitride semiconductor laser element according to claim 1, wherein the impurity having the local maximum is B and has an area density of 2×10¹² cm⁻² or more and 1×10¹⁵ cm⁻² or less.

9. The nitride semiconductor laser element according to claim 1, wherein a ratio of an arrangement area of the current confinement layer to an area of an element upper surface is 5% or more and less than 40%.

10. The nitride semiconductor laser element according to claim 1, wherein a difference in level on an element surface between the opening portion and the current confinement layer is four times or less a thickness of the current confinement layer.

11. The nitride semiconductor laser element according to claim 1, wherein a difference in level on an element surface between the opening portion and the current confinement layer is 300 nm or less.
